(19) United States
(12) Patent Application Publication
(10) Pub. No.: US 2014/0050864 A1
(43) Pub. Date: Feb. 20, 2014

(54) METHOD FOR PRODUCING LAMINATE

(71) Applicant: ASAHI GLASS COMPANY, LIMITED, Chiyoda-ku (JP)

(72) Inventors: Naoto KIHARA, Chiyoda-ku (JP); Takuya NAKAO, Chiyoda-ku (JP)

(73) Assignee: ASAHI GLASS COMPANY, LIMITED, Chiyoda-ku (JP)

(21) Appl. No.: 14/064,542

(22) Filed: Oct. 28, 2013

Related U.S. Application Data
(63) Continuation of application No. PCT/JP2012/060378, filed on Apr. 17, 2012.

(30) Foreign Application Priority Data
Apr. 27, 2011 (JP) 2011-099959

(51) Int. Cl. H01L 31/18

(52) U.S. Cl. CPC H01L 31/18
USPC 427/579; 427/569; 427/578

(57) ABSTRACT

To provide a method for producing a laminate excellent in weather resistance, gas barrier property and long-term stability of adhesion between layers.

A method for producing a laminate comprising a substrate sheet containing a fluororesin and a gas barrier film directly laminated on at least one side of the substrate sheet, wherein the gas barrier film contains as the main component an inorganic compound comprising at least one member selected from the group consisting of oxygen, nitrogen and carbon, and silicon or aluminum, and the gas barrier film is formed on the substrate sheet by a high-frequency plasma chemical vapor deposition method at a frequency of 27.12 MHz.

### TECHNICAL FIELD

The present invention relates to a method for producing a laminate.

### BACKGROUND ART

In recent years, from the viewpoint of the protection of the global environment, clean energy with higher safety, has been desired. Among clean energies which are expected in the future, particularly a solar cell is highly expected in terms of its cleanness, safety and easy operation.

The core to convert the sunlight put in a solar cell to electric energy is a cell. As the cell, one composed of a monocrystal, polycrystal or amorphous silicon type semiconductor is widely used. A plurality of the cells are usually wired in series or parallel, and further, they are protected with various materials for maintaining the function for a long period of time, and used as a solar cell module.

A solar cell module generally has a structure where the side of the cell hit by sunlight is covered with a tempered glass, the rear side is sealed with a back sheet, and a filer made of a thermoplastic resin (particularly an ethylene/vinyl acetate polymer (hereinafter referred to as “EVA”)) is filled in the space between the cell and the tempered glass and in the space between the cell and the back sheet, respectively.

Quality assurance of product for about 20 to 30 years is required for a solar cell module. Since the solar cell module is mainly used outside, weather resistance is required for the constituent material. Further, the tempered glass and back sheet have a role to prevent the deterioration caused by the moisture inside the module, and gas barrier property such as water vapor barrier property is also required.

Although the tempered glass is excellent in transparency, weather resistance, gas barrier property, etc., its plasticity, shock resistance, operatability and so on are low. Further, in recent years, production of a solar cell by Roll-to-Roll process has been studied for weight saving of a solar cell and cost reduction, however, the tempered glass cannot be used in such a field.

Therefore, the application of a resin sheet, particularly a fluororesin sheet excellent in weather resistance, has been considered, instead of the tempered glass. However, the resin sheet has a problem that gas barrier property is low as compared with the tempered glass.

To solve the above-mentioned problem, it has been proposed to provide an inorganic film. For example, Patent Document 1 proposes a protective sheet having a fluororesin sheet and a resin sheet having a vapor deposition thin film of an inorganic oxide, laminated. Further, Patent Document 2 proposes a protective sheet for a solar cell module having a deposition-resistant protective film on one side of a plastic sheet such as a fluororesin sheet provided, and further having a vapor deposition film of an inorganic oxide provided.

Such an inorganic film has gas barrier property and improves the moisture resistance., etc.

### PRIOR ART DOCUMENTS

### PATENT DOCUMENTS

Patent Document 1: JP-A-2000-138387

Patent Document 2: JP-A-2000-340818

### DISCLOSURE OF INVENTION

### Technical Problem

As a method for forming such an inorganic film, various methods have been known, ad particularly a sputtering method and a plasma chemical vapor deposition method (CVD) are considered to be capable of forming a dense film having high gas barrier property. However, by such a conventional film forming method, there is such a problem that if an inorganic film is directly formed on a substrate sheet containing a fluororesin, particularly in a case where a substrate sheet containing an ethylene/tetrafluoroethylene copolymer is used, the adhesion between them tends to be decreased. If the adhesion is decreased, when a solar cell module is constituted with a filler layer provided to be in contact with the inorganic film, the inorganic film may be peeled from the substrate sheet. If a space is formed between the inorganic film and the filler layer by peeling, e.g. by inclusion of moisture, the durability of the solar cell module may be decreased.

As a method for increasing the adhesion between the substrate sheet and the inorganic film, there may be a method of subjecting the substrate sheet surface to a surface treatment such as a corona discharge treatment. However, in such a case, although initial adhesion will be improved to a certain extent, the adhesion will hardly be maintained over a long period of time.

In a case where an inorganic film is formed on a non-fluororesin type resin sheet (e.g. polyethylene terephthalate film) as disclosed in Patent Document 1, the decrease in the adhesion is not problematic so much, however, the weather resistance of the resin sheet itself is insufficient.

Under these circumstances, it is an object of the present invention to provide a production method to obtain a laminate excellent in weather resistance, gas barrier property, and long-term stability of adhesion between layers.

### Solution to Problem

To achieve the above object, the present invention provides the following.
[1] A method for producing a laminate comprising a substrate sheet containing a fluororesin and a gas barrier film directly laminated on at least one side of the substrate sheet;

wherein the gas barrier film contains as the main component an inorganic compound comprising at least one member selected from the group consisting of oxygen, nitrogen and carbon, and silicon or aluminum; and

the gas barrier film is formed on the substrate sheet by a high-frequency plasma chemical vapor deposition method at a frequency of 27.12 MHz.
[2] The method for producing a laminate according to the above [1], wherein the fluororesin contains an ethylene/tetrafluoroethylene copolymer.
[3] The method for producing a laminate according to the above [1] or [2], wherein the inorganic compound is an inorganic silicon compound comprising silicon and at least one member selected from the group consisting of oxygen, nitrogen and carbon.
[4] The method for producing a laminate according to the above [3], wherein the inorganic compound is silicon nitride or silicon oxynitride.
[5] The method for producing a laminate according to any one of the above [1] to [4], wherein a gas to be a silicon source in the inorganic compound is SiH₄ or halogenated silane.
[6] The method for producing a laminate according to any one of the above [1] to [5], wherein the laminate has a visible light transmittance of at least 80%.
[7] The method for producing a laminate according to any one of the above [1] to [6], wherein the laminate is a protective sheet for a solar cell module.

### Advantageous Effects of Invention

According to the present invention, it is possible to provide a laminate excellent in weather resistance, gas barrier property, and long-term stability of adhesion between layers, and the obtained laminate can suitably be used as e.g. a protective sheet for a solar cell module.

### BRIEF DESCRIPTION OF DRAWINGS

FIG. 1 is a view schematically illustrating one embodiment of a film forming apparatus to be used for film forming by a plasma CVD method.

### DESCRIPTION OF EMBODIMENTS

The production method of the present invention is a method for producing a laminate comprising a substrate sheet containing a fluororesin and a gas barrier film directly laminated on at least one surface of the substrate sheet.

### <Substrate Sheet>

The fluororesin constituting the substrate sheet is not particularly limited so long as it is a thermoplastic resin containing fluorine atoms in the molecular structure of the resin, and various known fluororesins can be used. Specifically, a tetrafluoroethylene resin, a chlorotrifluoroethylene resin, a vinylidene fluoride resin, a vinyl fluoride resin or a composite of at least 2 of these resins may, for example, be mentioned. Among them, the tetrafluoroethylene resin or the chlorotrifluoroethylene resin is preferred, and the tetrafluoroethylene resin is particularly preferred, from the viewpoint of the excellence in particularly weather resistance, stain resistance and the like.

The tetrafluoroethylene resin may, for example, be specifically polytetrafluoroethylene (PTFE), a tetrafluoroethylene/perfluoro(alkoxyethylene) copolymer (PFA), a tetrafluoroethylene/hexafluoropropylene/perfluoro(alkoxyethylene) copolymer (EPE), a tetrafluoroethylene/hexafluoropropylene copolymer (FEP), an ethylene/tetrafluoroethylene copolymer (ETFE) or an ethylene/trichlorofluoroethylene copolymer (ETCFE).

As a case requires, these resins may further have a small amount of a comonomer component copolymerized respectively.

The comonomer component may be any monomer so long as it is copolymerizable with other monomers constructing each resin (for example, in the case of ETFE, ethylene and tetrafluoroethylene). For example, the following compounds may be mentioned.

A fluorinated ethylene such as CF₂═CFCl or CF₂═CH₂; a fluorinated propylene such as CF₂═CFCF₃ or CF₂═CHCF₃; a C₂₋₁₀ fluorinated alkylethylene having a fluoroalkyl group such as CH₂═CHC₂F₅, CH₂═CHC₄F₉, CH₂═CFC₄F₉ or CH₂═CF(CF₂)₃H; a perfluoro(alkyl vinyl ether) such as CF₂═CFO(CF₂CFXO)ₘR^{f} (wherein R^{f} is a C₁₋₆ perfluoroalkyl group, X is a fluorine atom or a trifluoromethyl group, and m is an integer of from 1 to 5); or a vinyl ether having a group capable of being converted to a carboxylic acid group or a sulfonic acid group, such as CF₂═CFOCF₂CF₂CF₂COOCH₃ or CF₂═CFOCF₂CF(CF₃)OCF₂CF₂SO₂F, may be mentioned.

As the tetrafluoroethylene resin, among them, PFA, FEP, ETFE or ETCFE is preferred, and particularly, ETFE is preferred from the viewpoint of cost, mechanical strength, film forming property and the like.

ETFE is a copolymer mainly composed of ethylene units and tetrafluoroethylene units. Here, “unit” means a repeating unit constituting a polymer.

In all the units constituting ETFE, the total content of the ethylene units and the tetrafluoroethylene units is preferably at least 90 mol %, more preferably at least 95 mol %, and may be 100 mol %.

In ETFE, the molar ratio of the ethylene units/the tetrafluoroethylene units is preferably from 40/60 to 70/30, more preferably from 40/60 to 60/40.

As a case requires, ETFE may contain a small amount of comonomer component units. As the comonomer component in the comonomer component units, the same one as mentioned above may be mentioned.

In a case where ETFE contains comonomer component units, the content of the comonomer component units in all the units constituting ETFE is preferably from 0.3 to 10 mol %, more preferably from 0.3 to 5 mol %.

As the chlorotrifluoroethylene resin, for example, one obtained by substituting tetrafluoroethylene of the tetrafluoroethylene resin with chlorotrifluoroethylene may be mentioned. Specifically, a chlorotrifluoroethylene homopolymer (CTFE) or an ethylene/chlorotrifluoroethylene copolymer (ECTFE) may, for example, be mentioned.

The fluororesin contained in a substrate sheet may be one type or two or more types.

The substrate sheet may be one made of only a fluororesin, or one made of a mixed resin of a fluororesin and other thermoplastic resin. However, considering the effect of the present invention, it is preferred that the substrate sheet contains a fluororesin as the main component. The proportion of the fluororesin in the substrate sheet is preferably at least 50 mass %, more preferably at least 70 mass %, based on the total mass of the substrate sheet.

Such other thermoplastic resin may, for example, be an acrylic resin, a polyester resin, a polyurethane resin, a nylon resin, a polyethylene resin, a polyimide resin, a polyamide resin, a polyvinyl chloride resin or a polycarbonate resin.

Further, it is possible to apply a resin obtained by mixing e.g. an additive and filler such as pigment, ultraviolet absorber, carbon black, carbon fiber, silicon carbide, glass fiber or mica.

The shape and size of the substrate sheet may be optionally decided according to the purpose, and are not particularly limited. For example, in a case where the laminate is used for a protective sheet for a solar cell module, they may be optionally decided according to the shape and size of the solar cell module.

The thickness of the substrate sheet is preferably at least 10 μm, more preferably at least 20 μm from the viewpoint of the strength. The upper limit of the thickness may be decided optionally according to the purpose, and is not limited. For example, in a case where the laminate is used for a protective sheet which is provided on the side of the cell of a solar cell module, where sunlight hits, the thickness of the substrate sheet is preferably thinner from the viewpoint of the improvement of power generation efficiency by high light transmittance. Specifically, it is preferably at most 200 μm, more preferably at most 100 μm, particularly preferably at most 60 μm. The thickness of the substrate sheet is usually at least 10 μm.

### <Gas Barrier Film>

The gas barrier film contains as the main component an inorganic compound comprising at least one element selected from the group consisting of oxygen, nitrogen and carbon, and silicon (element) or aluminum (element). By containing the inorganic compound as the main component, the transparency, the water vapor barrier property and the like of the gas barrier film to be formed will be improved.

Here, “containing as the main component” means that the proportion of the inorganic compound in the gas barrier film is at least 95 mol %. The proportion of the inorganic compound in the gas barrier film is preferably 100 mol %. That is, the gas barrier film preferably consists of the inorganic compound.

The inorganic compound may be an inorganic silicon compound comprising silicon and at least one member selected from the group consisting of oxygen, nitrogen and carbon, or may be an inorganic aluminum compound comprising aluminum and at least one member selected from the group consisting of oxygen, nitrogen and carbon.

The inorganic compound may be more specifically an oxide, a nitride, an oxynitride, an oxynitride carbide or the like of silicon or aluminum. Specific examples thereof include silicon oxide (hereinafter referred to as SiO₂), silicon nitride (hereinafter referred to as SiN), silicon oxynitride (hereinafter referred to as SiON), silicon oxynitride carbide (hereinafter referred to as SiONC), aluminum oxide (hereinafter referred to as Al₂O₃) and aluminum nitride (hereinafter referred to as AlN).

As the inorganic compound, among them, preferred is an inorganic silicon compound such as SiO₂, SiN, SiON or SiONC from such a viewpoint that the inorganic compound deposited on the inner wall of a vacuum container of a film forming apparatus at the time of film forming can be removed by plasma etching employing a fluorine gas, and the maintenance is easy, more preferred is at least one member selected from the group consisting of SiN, SiON and SiONC, particularly preferred is SiN or SiON.

The gas barrier film may be a single layer or may be a laminate of a plurality of layers differing in the material (e.g. the inorganic compound as the main component).

The single layer here means a layer formed by one film forming operation.

In the present invention, by employing a high-frequency plasma CVD method at a frequency of 27.12 MHz, even when the gas barrier film is a single layer, it has sufficient gas barrier property and is also excellent in the long-term stability of the adhesion to a substrate sheet.

The thickness (the total thickness in a case where the gas barrier film is a laminate of a plurality of layers) of the gas barrier film is preferably at least 0.5 nm with a view to securing the adhesion to a substrate sheet, securing gas barrier property, etc., particularly preferably at least 10 nm. Further, it is preferably at most 200 nm with a view to maintaining the light transmittance, maintaining the flexibility of the laminate, securing the adhesion to a substrate sheet, etc., particularly preferably at most 150 nm.

The gas barrier film may be provided on one side or on both sides of the substrate sheet. It is preferably formed on one side in view of the productivity and practicability.

### <Method for Forming Gas Barrier Film>

In the present invention, the gas barrier film is formed on the substrate sheet by a high-frequency plasma chemical vapor deposition method at a frequency of 27.12 MHz (hereinafter sometimes referred to as 27.12 MHz plasma CVD method).

By employing 27.12 MHz plasma CVD method, a gas barrier film excellent in the gas barrier property can be formed, and in addition, the adhesion between the substrate sheet and the gas barrier film of the obtained laminate and its long-term stability (long-term adhesion stability) can be improved.

Here, the high-frequency plasma CVD method is a method of applying a voltage to between electrodes facing each other by a high-frequency power source to form material gas into plasma, thereby to form a vapor deposition film on the surface of a substrate disposed between the electrodes.

Heretofore, in a case where an inorganic thin film is formed on a resin sheet by a high-frequency plasma CVD method, as the frequency of the high-frequency power source, 13.56 MHz which is the lowest in the industrial frequency has been employed. Although use of the high-frequency plasma CVD at 27.12 MHz in a semiconductor field or the like has been slightly reported, its utilization field has been limited due to a small treatment area, a high apparatus cost and the like.

The reason why the long-term adhesion stability is improved by employing the 27.12 MHz plasma CVD method is not clear, but is estimated because the substrate sheet surface is less likely to be damaged at the time of film forming as compared with a case of using another film forming method (such as sputtering method or high-frequency plasma CVD method at 13.56 MHz). The present inventors have noted the relation between the adhesion and the adhesion durability and the film forming process for the gas barrier film and conducted various studies and as a result, found the following. That is, in a case where a gas barrier film is formed by a process utilizing plasma such as a sputtering method or a plasma CVD method, the fluororesin (such as ETFE) on the substrate sheet surface is damaged by the plasma etching and its molecular weight is reduced. A layer constituted by such a fluororesin, the molecular weight of which is reduced, is called a weak boundary layer (hereinafter referred to as WBL), and its initial adhesion is weak due to the weak boundary, and in addition, molecules are broken from WBL in long-term use, whereby the adhesion durability is impaired. In the case of the 27.12 MHz plasma CVD method, as compared with the case of 13.56 MHz, WBL is less likely to be formed by the ion impact reduced by reduction of the plasma potential, a small temperature increase of the substrate sheet, and the like.

Formation of a gas barrier film by the 27.12 MHz plasma CVD method may be carried out by, as a film forming apparatus, a known high-frequency plasma CVD method equipped with a high-frequency power source at a frequency of 27.12 MHz.

For example, in the case of using a batch type high-frequency plasma CVD apparatus, the gas barrier film can be formed by the following steps.

In a vacuum container provided with a pair of electrodes disposed with a distance in its interior, a substrate sheet is disposed between the pair of electrodes, the pressure in the vacuum container is reduced, and material gas is introduced into the vacuum container and in addition, a voltage is applied to between the pair of electrodes by a high-frequency power source at a frequency of 27.12 MHz.

By applying a voltage as mentioned above, the material gas introduced into the vacuum container is decomposed by plasma and deposited on the substrate sheet surface to form the gas barrier film.

Now, the method for forming a gas barrier film by the 27.12 MHz plasma CVD method will be described in detail with reference to one embodiment.

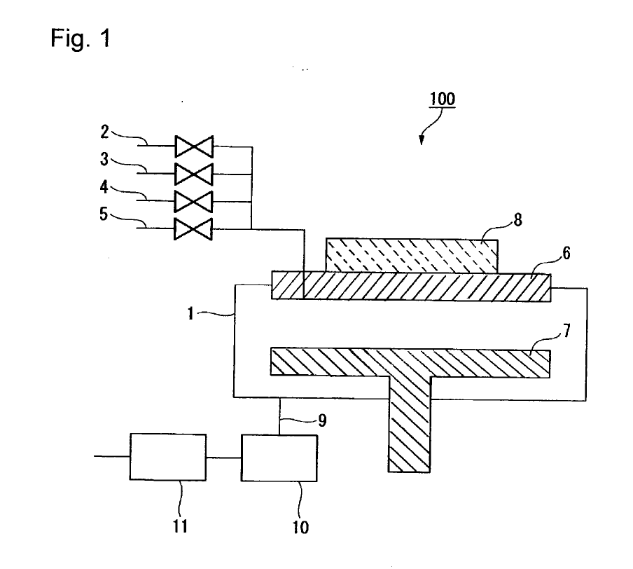

FIG. 1 is a view schematically illustrating one embodiment of a batch type high-frequency plasma CVD apparatus 100 to be used for film forming by the 27.12 MHz plasma CVD method.

The high-frequency plasma CVD apparatus 100 comprises a vacuum container 1, material gas supply lines 2 to 5 to supply the material gas to the vacuum container 1, a pair of electrodes 6 and 7 facing each other in the vacuum container 1, a high-frequency power source 8 at a frequency of 27.12 MHz to apply a voltage to between the electrodes 6 and 7, and an exhaust line 9 to reduce the pressure in the vacuum container 1 to bring the vacuum container 1 in a vacuum state, and on the exhaust line 9, a turbomolecular pump 10 and a rotary pump 11 are provided.

Formation of a gas barrier film by using the high-frequency plasma CVD apparatus 100 can be carried out by the following procedure for example.

First, a substrate sheet is disposed on the electrode 7 of the high-frequency plasma CVD apparatus 100, and the pressure in the vacuum container 1 is reduced by the turbomolecular pump 10 and the rotary pump 11 to make the interior in a vacuum state. The pressure in the chamber 1 is preferably at most 9×10⁻⁴ Pa, more preferably at most 1×10⁻⁴ Pa, whereby impurities in the film are likely to be eliminated. Further, the pressure in the chamber 1 is usually at least 1×10⁻⁵ Pa in view of the productivity by the evacuation time.

Then, into the vacuum container 1 in a vacuum state, a material gas is supplied from at least one of the material gas supply lines 2 to 5 and in addition, a voltage is applied to between the electrodes 6 and 7 by the high-frequency power source 8, whereby the material gas is decomposed by plasma, and atoms or molecules of the material gas are deposited on the substrate sheet to form a film (gas barrier film). On that occasion, the pressure (film forming pressure) in the chamber 1 is preferably within a range of from 0.1 to 50 Pa, more preferably within a range of from 1 to 30 Pa. By the pressure being at most 50 Pa, formation of dust and deterioration of the gas barrier property can further be suppressed. By the pressure being at least 0.1 Pa, discharge is easily carried out.

The thickness of the gas barrier film can be adjusted by the film forming time (a time over which supply of the material gas and application of a voltage are carried out).

The material gas is determined depending upon the composition of the gas barrier film to be formed. For example, in the case of forming a gas barrier film containing an inorganic silicon compound as the main component, at least gas to be a Si source is used, and in the case of forming a gas barrier film containing an inorganic aluminum compound as the main component, at least gas to be an Al source is used and as the case requires, gas to be a N source (such as ammonia (NH₃) gas or nitrogen (N₂) gas), gas to be an O source (such as oxygen (O₂) gas) or the like is used in combination.

The gas to be a Si source may be gas containing a silane compound, and the silane compound may, for example, be silane (SiH₄) or halogenated silane having some or all the hydrogen atoms of a silane substituted by halogen atoms such as chlorine atoms or fluorine atoms.

The gas to be an Al source may, for example, be trimethylaluminum (TMA).

In a case where a plurality of material gases are used in combination, it is preferred that they are respectively supplied from separate material gas supply lines.

For example, SiH₄ gas is supplied from the material gas supply line 2, NH₃ gas from the material gas supply line 3 and the N₂ gas from the material gas supply line 4, whereby a SiN film can be formed. Further, O₂ gas is further supplied from the material gas supply line 5, a SiON film can be formed.

The method of forming the gas barrier film is not limited to the above embodiment. For example, a roll-two-roll film forming apparatus, not batch type, may be used.

According to the above-described production method of the present invention, a laminate excellent in the weather resistance, the gas barrier property and the long-term adhesion stability can be obtained.

That is, the laminate is excellent in the weather resistance since the substrate sheet on which the gas barrier film is directly laminated contains a fluororesin. Further, it is also excellent in the heat resistance, the chemical resistance, and the like. Further, since the gas barrier film containing the inorganic compound as the main component is directly laminated on the substrate sheet, as compared with a case where another layer is present between them, the entire laminate is also excellent in the weather resistance, the heat resistance, the chemical resistance and the like. Further, by employing the 27.12 MHz plasma CVD method, a gas barrier layer excellent in the gas barrier property and having favorable adhesion to the substrate sheet can be formed, and further, a decrease of the adhesion with time can be suppressed.

Therefore, the laminate of the present invention is useful as a protective sheet for a solar cell module.

For example, in a solar cell module wherein the laminate having long-term adhesion stability is disposed so that the face on the gas barrier film side is on the side of the filler layer of e.g. EVA, a decrease in the adhesive strength between the substrate sheet and the filler layer hardly occurs.

Further, the substrate sheet containing a fluororesin is excellent in the weather resistance, the heat resistance, the chemical resistance and further the stain resistance. Therefore, when the laminate is provided so that the outermost layer of the solar cell module is the substrate sheet, it is possible to prevent the performance from decreasing by stains for a long period of time, since dust or trash is unlikely to be attached to the surface of the solar cell module.

Accordingly, a solar cell module having high quality over a long period of time can be obtained by using the laminate of the present invention as a protective sheet for the solar cell module.

Further, in the laminate, the substrate sheet is highly transparent, and also with respect to the gas barrier film, its high transparency can be achieved by properly selecting the material and the thickness. When the gas barrier film has high transparency, the transparency of the whole laminate is also high, and such a laminate can be used as a protective sheet for protecting the side of the cell where sunlight hits in the solar cell module.

In a case where the laminate of the present invention is used as a protective sheet for protecting the side of the cell where sunlight hits in the solar cell module, the visible light transmittance of the laminate is preferably at least 80%, more preferably at least 90%. The upper limit is not particularly limited since the higher the visible light transmittance, the better. However, it is practically about 98%.

Further, the application of the laminate of the present invention is not limited to a protective sheet for a solar cell module, and the laminate of the present invention can be used for various applications for which the weather resistance and the gas barrier property are required. Examples of such applications include a protective sheet for a display, a protective sheet for an organic EL illumination, a protective film member for an organic EL display, a protective film member for electronic paper, a mirror protective member for a solar heat power generation, a food packaging member, and a medical packaging member.

### EXAMPLES

Now, the present invention will be described in detail with reference to specific Examples of the above embodiment. However, the present invention is not limited to the following specific Examples.

Now, measurement method and evaluation methods employed in Examples are shown.

### <Measurement of Thickness of Gas Barrier Film>

The thickness of a gas barrier film (such as a SiN film, a SiON film or an Al₂O₃ film) was measured by a spectral ellipsometry device (tradename “M-2000DI” manufactured by J.A.WOOLLAM Japan), and calculated by carrying out optical fitting by WVASE32 (manufactured by J.A.WOOLLAM).

### <Evaluation of Adhesion (Measurement of Adhesive Strength)>

One having the laminate obtained in each Example cut to a size of 10 cm×10 cm and an EVA film (manufactured by Bridgestone Corporation, W25CL) cut to the same size were laminated in the order or ETFE film/gas barrier film/EVA film, followed by thermocompression bonding under condition of pressure of 10 kgf/cm by press machine (manufactured by Asahi Glass Company, Limited), area of 120 cm², temperature of 150° C. and time of 10 minutes to obtain a test specimen.

Then, each test specimen was cut to a size of 1 cm×10 cm, and using a TENSILON universal testing machine (RTC-1310A) manufactured by Orientic Co., Ltd., adhesive strength (peeling adhesive strength, unit: N/cm) was measured by 180° peeling test in accordance with JIS K6854-2 at a pulling rate of 50 mm/min.

The measurement of the adhesive strength was carried out before (initial stage) and after (after 100 hours and after 3,000 hours) of the following weathering test (SWOM). However, measurement after 3,000 hours was not carried out for one having the initial adhesive strength of less than 3 N/cm after 100 hours.

Weathering test (SWOM): Carried out by using a sunshine carbon arc lamp weathering test machine (Sunshine Weather Meter S300 manufactured by Suga Test Instruments Co., Ltd.) in accordance with JIS B7753.

### <Evaluation of Water Vapor Barrier Property (Measurement of Water Vapor Transmission Rate)>

The water vapor transmission rate (hereinafter referred to as WVTR) of the laminate obtained in each Example was measured by dish method in accordance with JIS Z0208.

WVTR represents the amount of water vapor which passes through a membrane-form material with a unit area for a certain time, and JIS Z0208 defines WVTR of a material as a mass of water vapor which passes a boundary surface in 24 hours calculated per 1 m² of the material (unit: g/m²/day), employing a moisture-proof packaging material as the boundary surface at a temperature of 25° C. or 40 ° C., the air on one side being a relative humidity of 90% and the other side being maintained in a dry state with an adsorbent.

In Examples, the laminate in each Example was used as the moisture-proof packaging material, and WVTR at a temperature of 40° C. was measured.

### <Overall Evaluation>

Overall evaluation of the long-term adhesion stability and the moisture-proof property was carried out based on the following evaluation standards from the results of measurement of the adhesive strength and the water vapor transmission rate.

◯: One having an adhesive strength after 3,000 hours of SWOM being at least 3 N/cm and WVTR being at most 0.1 g/m²/day.

×: One which corresponds to at least one of (1) the adhesive strength after 100 hours of SWOM or after 3,000 hours of SWOM being less than 3N/cm and (2) WVTR exceeding 0.1 g/m²/day.

### Example 1

Using an apparatus having the same structure as the high-frequency plasma CVD apparatus 100 shown in FIG. 1, forming of a SiN film was carried out by a high-frequency plasma CVD method by the following procedure.

A substrate (ETFE film having a thickness of 100 μm, tradename: Aflex, manufactured by Asahi Glass Company, Limited) was placed inside a vacuum container 1 of the apparatus, and the pressure in the container was reduced to a vacuum of about 6×10⁻⁴ Pa (5×10⁻⁶ torr), and 50 sccm of SiH₄ gas was introduced from a material gas supply line 2,600 sccm of NH₃ gas from a material gas supply line 3 and 850 sccm of N₂ gas from a material gas supply line 4. A voltage was applied at a current density of 0.6 W/cm² by a high-frequency power source 8 at a frequency of 27.12 MHz to form 100 nm of a SiN film (gas barrier film) on the substrate. The pressure in the chamber at the time of film forming was 20 Pa.

With respect to the obtained laminate, the adhesion and the water vapor barrier property were evaluated by the above procedure. Further, from the above results, overall evaluation was made. The results are shown in Table 1.

### Comparative Example 1

Using a high-frequency plasma CVD apparatus with a high-frequency power source at a frequency of 13.56 MHz, forming of a SiN film was carried out by a high-frequency plasma CVD method by the following procedure.

A substrate (ETFE film having a thickness of 100 μm, tradename: Aflex, manufactured by Asahi Glass Company, Limited) was placed inside a vacuum container of the apparatus, and the pressure in the container was reduced to a vacuum of about 6×10⁻⁴ Pa (5×10⁻⁶ torr), and 180 sccm of SiH₄ gas, 540 sccm of NH₃ gas and 1,800 sccm of N₂ as were introduced. A voltage was applied at a current density of 1.0 W/cm² by a high-frequency power source at a frequency of 13.56 MHz to form 100 nm of a SiN film (gas barrier film) on the substrate. The pressure in the chamber at the time of film forming was 1 Pa.

With respect to the obtained laminate, the adhesion and the water vapor barrier property were evaluated by the above procedure. Further, from the above results, overall evaluation was made. The results are shown in Table 1.

### Comparative Example 2

Using a high-frequency plasma CVD apparatus with a high-frequency power source at a frequency of 13.56 MHz, forming of a SiN film was carried out by a high-frequency plasma CVD method by the following procedure.

A substrate (ETFE film having a thickness of 100 μm, tradename: Aflex, manufactured by Asahi Glass Company, Limited) was placed inside a vacuum container of the apparatus, and the pressure in the container was reduced to a vacuum of about 6×10⁻⁴ Pa (5×10⁻⁶ torr), and 180 sccm of SiH₄ gas, 540 sccm of NH₃ gas, 1,800 sccm of N₂ gas and 300 sccm of O₂ gas were introduced. A voltage was applied at a current density of 1.0 W/cm² by a high-frequency power source at a frequency of 13.56 MHz to form 100 nm of a SiN film (gas barrier film) on the substrate. The pressure in the chamber at the time of film forming was 1 Pa.

With respect to the obtained laminate, the adhesion and the water vapor barrier property were evaluated by the above procedure. Further, from the above results, overall evaluation was made. The results are shown in Table 1.

### Comparative Example 3

A substrate (ETFE film having a thickness of 100 μm, tradename: Aflex, manufactured by Asahi Glass Company, Limited) was placed inside an electron beam vapor deposition apparatus, and the pressure in the apparatus was reduced to a vacuum of about 6×10⁻⁴ Pa (5×10⁻⁶ torr), and then using alumina granules as the material, 3 sccm of O₂ gas was introduced into the chamber. The electric current was set at 100 mA, and the shutter opening and closing time was controlled to form 20 nm of an aluminum oxide thin film.

With respect to the obtained laminate, the adhesion and the water vapor barrier property were evaluated by the above procedure. Further, from the above results, overall evaluation was made. The results are shown in Table 1.

### Comparative Example 4

A substrate (ETFE film having a thickness of 100 μm, tradename: Aflex, manufactured by Asahi Glass Company, Limited) was placed inside a sputtering apparatus, the pressure in the apparatus was reduced to a vacuum of about 6×10⁻⁴ Pa (5×10⁻⁶ torr), and using aluminum as a target, 50 sccm of Ar gas and 3 sccm of O₂ gas were introduced into the chamber, followed by discharge at a DC voltage of 320 V. The shutter was opened and closed to control the film forming time, to form 20 nm of an aluminum oxide thin film.

With respect to the obtained laminate, the adhesion and the water vapor barrier property were evaluated by the above procedure. Further, from the above results, overall evaluation was made. The results are shown in Table 1.

### Comparative Example 5

A substrate (ETFE film having a thickness of 100 μm, tradename: Aflex, manufactured by Asahi Glass Company, Limited) was placed on a substrate holder in a vacuum container of a catalytic CVD apparatus, and the distance between a catalyzer (tungsten wire) and the substrate surface was set to 200 mm. The pressure in the chamber was reduced to a vacuum of at most 5×10⁻⁴ Pa by a turbomolecular pump and a rotary pump, and as material gases, 8 sccm of SiH₄ gas, 50 sccm of NH₃ gas and 1,200 sccm of H₂ gas were introduced from a first material gas supply line, and the catalyzer was heated to 1,800° C. to form 100 nm of a SiN film (gas barrier layer) on the substrate. The pressure in the chamber at the time of film forming was 30 Pa.

With respect to the obtained laminate, the adhesion and the water vapor barrier property were evaluated by the above procedure. Further, from the above results, overall evaluation was made. The results are shown in Table 1.

### Comparative Example 6

A substrate (ETFE film having a thickness of 100 μm, tradename: Aflex, manufactured by Asahi Glass Company, Limited) was placed on a substrate holder in a vacuum container of a catalytic CVD apparatus, and the distance between a catalyzer (tungsten wire) and the substrate surface was set to 200 mm. The pressure in the chamber was reduced to a vacuum of at most 5×10⁻⁴ Pa by a turbomolecular pump and a rotary pump, and as material gases, 8 sccm of SiH₄ gas, 50 sccm of NH₃ gas and 1,200 sccm of H₂ gas were introduced from a first material gas supply line and 5 sccm of O₂ gas from a second material gas supply line, and the catalyzer was heated to 1,800° C. to form 100 nm of a SiON film (gas barrier layer) on the substrate. The pressure in the chamber at the time of film forming was 30 Pa.

With respect to the obtained laminate, the adhesion and the water vapor barrier property were evaluated by the above procedure. Further, from the above results, overall evaluation was made. The results are shown in Table 1.

### Reference Example A

Using a high-frequency plasma CVD apparatus with a high-frequency power source at a frequency of 13.56 MHz, forming of a SiN film was carried out by a high-frequency plasma CVD method by the following procedure.

A substrate (polyethylene naphthalate (PEN) film having a thickness of 100 μm, tradename: Teonex, manufactured by Teijin DuPont Films Japan Limited) was placed inside a vacuum container of the apparatus, the pressure in the container was reduced to a vacuum of about 6×10⁻⁴ Pa (5×10^{'16} torr), and 180 sccm of SiH₄ gas, 540 sccm of NH₃ gas and 1,800 sccm of N₂ gas were introduced. By the high-frequency power source at a frequency of 13.56 MHz, a voltage was applied at a current density of 1.0 W/cm² to form 100 nm of a SiN film (gas barrier film) on the substrate. The pressure in the chamber at the time of film forming was 20 Pa.

With respect to the obtained laminate, the adhesion and the water vapor barrier property were evaluated by the above procedure. The results are shown in Table 1.

TABLE 1

| | Gas barrier film | | | Adhesive strength (N/cm) | | | |
|---|---|---|---|---|---|---|---|
| | | Film forming | WVTR | | SWOM | SWOM | Overall |
| | Material | method | (g/m²/day) | Initial | 100 h | 3000 h | evaluation |
| Ex. 1 | SiN | High-frequency | 0.1 | 26.6 | 21.2 | 9.7 | ∘ |
| | | plasma CVD | | | | | |
| | | (27.12 MHz) | | | | | |
| Comp. | SiN | High-frequency | 0.1 | 22.2 | 0 | — | x |
| Ex. 1 | | plasma CVD | | | | | |
| | | (13.56 MHz) | | | | | |
| Comp. | SiON | High-frequency | 0.1 | 20.8 | 0.4 | — | x |
| Ex. 2 | | plasma CVD | | | | | |
| | | (13.56 MHz) | | | | | |
| Comp. | Al₂O₃ | Vapor | 4.5 | 9.4 | 7.2 | 2.9 | x |
| Ex. 3 | | deposition | | | | | |
| Comp. | Al₂O₃ | Sputtering | 0.1 | 0 | — | — | x |
| Ex. 4 | | | | | | | |
| Comp. | SiN | Catalytic CVD | 0.1 | 17 | 5.1 | 0.1 | x |
| Ex. 5 | | | | | | | |
| Comp. | SiON | Catalytic CVD | 0.1 | 23.4 | 20.9 | 0.7 | x |
| Ex. 6 | | | | | | | |
| Ref. | SiN | High-frequency | 0.1 | 12.1 | 22.3 | 20.4 | — |
| Ex. A | | plasma CVD | | | | | |
| | | (13.56 MHz) | | | | | |

As shown in Table 1, the laminate in Example 1 having a gas barrier film formed by the high-frequency plasma CVD method at a frequency of 27.12 MHz, had WVTR of 0.1 g/m²/day which is the measurement limit by dish method, and had excellent water vapor barrier property. Further, it had a high initial adhesive strength when laminated with the EVA film, and its decrease in the adhesive strength by SWOM was also suppressed.

On the other hand, each of the laminates in Comparative Examples 1 and 2 having a gas barrier film formed by a high-frequency plasma CVD method at a frequency of 13.56 MHz had favorable water vapor barrier property and initial adhesive strength, but its adhesive strength was remarkably decreased by SWOM.

The laminate in Comparative Example 3 having a gas barrier film formed by a vapor deposition method had a low water vapor barrier property.

The laminate in Comparative Example 4 having a gas barrier film formed by a sputtering method had a favorable water vapor barrier property but had low initial adhesive strength and adhesive strength after SWOM.

Each of the laminates in Comparative Examples 5 and 6 having a gas barrier film formed by a catalytic CVD method had a favorable water vapor barrier property, but its adhesive strength was remarkably decreased after 3,000 hours of SWOM.

As evident from the results of Reference Example A in which a PEN film was used as the substrate sheet, the decrease in the adhesive strength by SWOM is a problem characteristic to a case where the substrate sheet contains a fluororesin such as ETFE.

### INDUSTRIAL APPLICABILITY

The laminate obtainable by the present invention is excellent in weather resistance, gas barrier property and long-term stability of adhesion between layers, and is industrially useful as various protective members such as a protective sheet for a solar cell module, a protective sheet for a display, a protective film member for an organic EL illumination, a protective film member for an organic EL display, a protective film member for electronic paper, a mirror protective member for a solar heat power generation, a food packaging member, and a medical packaging member.

This application is a continuation of PCT Application No. PCT/JP2012/060378, filed on Apr. 17, 2012, which is based upon and claims the benefit of priority from Japanese Patent Application No. 2011-099959 filed on Apr. 27, 2011. The contents of those applications are incorporated herein by reference in its entirety.

### REFERENCE SYMBOLS

1: vacuum container, 2: material gas supply line, 3: material gas supply line, 4: material gas supply line, 5: material gas supply line, 6: first electrode, 7: second electrode, 8: high-frequency power source, 9: exhaust line, 10: turbomolecular pump, 11: rotary pump, 100: high-frequency plasma CVD apparatus

What is claimed is:

1. A method for producing a laminate comprising a substrate sheet containing a fluororesin and a gas barrier film directly laminated on at least one side of the substrate sheet;
wherein the gas barrier film contains as the main component an inorganic compound comprising at least one member selected from the group consisting of oxygen, nitrogen and carbon, and silicon or aluminum; and
the gas barrier film is formed on the substrate sheet by a high-frequency plasma chemical vapor deposition method at a frequency of 27.12 MHz.

2. The method for producing a laminate according to claim 1, wherein the fluororesin contains an ethylene/tetrafluoroethylene copolymer.

3. The method for producing a laminate according to claim 1, wherein the inorganic compound is an inorganic silicon compound comprising silicon and at least one member selected from the group consisting of oxygen, nitrogen and carbon.

4. The method for producing a laminate according to claim 3, wherein the inorganic compound is silicon nitride or silicon oxynitride.

5. The method for producing a laminate according to claim 1, wherein a gas to be a silicon source in the inorganic compound is SiH₄ or halogenated silane.

6. The method for producing a laminate according to claim 1, wherein the laminate has a visible light transmittance of at least 80%.

7. The method for producing a laminate according to claim 1, wherein the laminate is a protective sheet for a solar cell module.
